(19) United States
(12) Patent Application Publication
(10) Pub. No.: US 2009/0158856 A1
(43) Pub. Date: Jun. 25, 2009

(54) CAPACITIVE STRAIN GAUGE SYSTEM AND METHOD

(76) Inventors: Divyasimha Harish, Fremont, CA (US); John Schultz, Santa Clara, CA (US)

Correspondence Address: Intellevate, P.O. Box 52050, Minneapolis, MN, 55402, US

(21) Appl. No.: 12/343,164

(22) Filed: Dec. 23, 2008

Related U.S. Application Data
(60) Provisional application No. 61/016,466, filed on Dec. 23, 2007.

(51) Int. Cl. G01L 1/14; G01R 27/26

(52) U.S. Cl. 73/780; 324/660

(57) ABSTRACT

A system and methods of a capacitive strain gauge are disclosed. In one embodiment, a system includes a conductive element of a capacitive structure attached to a surface. The conductive element is comprised of an elongated member. An additional conductive element of the capacitive structure is attached to the surface, and the additional conductive element is comprised of an additional elongated member. The system includes an electrode coupled to the conductive element that applies a voltage to the conductive element when a capacitance is being determined. The system further includes an additional electrode coupled to the additional conductive element that receives an amplitude to determine a change in capacitance caused by a shape alteration of at least one of the conductive element, the additional conductive element, and a space between the conductive element and the additional conductive element.

### CLAIM OF PRIORITY

This application claims priority from U.S. Provisional Patent Application No. 61/016,466 filed on Dec. 23, 2007.

### FIELD OF TECHNOLOGY

This disclosure relates generally to the technical fields of measurement devices and, in one example embodiment, to a method and system of a capacitive strain gauge.

### BACKGROUND

A resistive strain gauge is a device used to measure deformation (strain) of an object. The resistive strain gauge may consist of an insulating flexible backing which supports a metallic foil pattern. The resistive strain gauge may be attached to the object by a suitable adhesive (e.g., cyanoacrylate). As the object is deformed, the foil may become deformed, causing its electrical resistance to change. The resistive strain gauge may be limited because of the metallic foil pattern and use of resistance to measure strain. For example, the resistive strain gauge may have a very small change in resistance with the load. Furthermore, an adhesive used in the resistive strain gauge may crack, peel and/or change properties with time, changing an accuracy of a measurement of the resistive strain gauge.

In addition, the resistive strain gauge may be susceptible to variances in electrical fields and temperature, may require too much compensation to measure strain, may not work well in cases of out-of-plane forces, and may not fit in many locations where a non-traditional form factor is required to measure strain.

### SUMMARY

A system and methods of a capacitive strain gauge are disclosed. In one aspect, a system includes a conductive element of a capacitive structure attached to a surface. The conductive element is comprised of an elongated member. An additional conductive element of the capacitive structure is attached to the surface, and the additional conductive element is comprised of an additional elongated member. The system includes an electrode coupled to the conductive element that applies a voltage to the conductive element when a capacitance is being determined. The system further includes an additional electrode coupled to the additional conductive element that receives an amplitude to determine a change in capacitance caused by a shape alteration of at least one of the conductive element, the additional conductive element, and a space between the conductive element and the additional conductive element.

The additional conductive element may be substantially parallel to the conductive element. The conductive element may be comprised of a plurality of elongated members coupled together, and wherein the additional conductive element is comprised of a plurality of additional elongated members coupled together. The system may further include a shield that substantially covers the conductive element and the additional conductive element to reduce a stray capacitance. The shield may substantially surround the conductive element and the additional conductive element. The system may include an amplifier module to reduce a capacitance of the shield below a threshold level.

A form change of the surface may determine the shape alteration of at least one of the conductive element, the additional conductive element, and a shape between the conductive element and the additional conductive element. A capacitance change may result from the shape alteration of at least one of at least one of the conductive element, the additional conductive element, and a space between the conductive element and the additional conductive element.

A form change of the surface may cause a proportional area alteration of a conductive element and a shape and causes a capacitance change below a threshold level. The system may further include a common dielectric used between each capacitive structure in the system to make an environmental condition affect each capacitive structure proportionately. The system may further include a reference capacitive structure coupled to the system to generate a capacitance based on an environmental factor and to compensate a measurement affected by the environmental factor.

The system may include a plurality of capacitive structures coupled to the surface, wherein a difference in capacitance between the plurality of capacitive structures is used to detect an uneven force when it is applied to the surface. The system may further include an energy harvesting module that acquires power to apply the voltage to the conductive element.

In another aspect, a method includes altering a shape of a part of a capacitive structure using a form change of a surface. The capacitive structure is comprised of one or more of a conductive element, an additional conductive element, and a space between the conductive element and the additional conductive element. The method further includes applying a voltage to an electrode coupled to the conductive element. The method also includes detecting an amplitude of an additional electrode coupled to the conductive element to determine a change in capacitance of the capacitive structure caused by a shape change of the surface.

The additional conductive element may be substantially parallel to the conductive element. The conductive element may be comprised of a plurality of elongated members coupled together. The additional conductive element may include multiple additional elongated members coupled together. The method may include reducing a stray capacitance using a shield that substantially covers the conductive element and the additional conductive element.

In yet another aspect, a method may include forming a conductive element of a capacitive structure attached to a surface. The conductive element includes an elongated member. The method includes placing an additional conductive element in the capacitive structure attached to the surface. The additional conductive element includes an additional elongated member. The method further includes coupling an electrode to the conductive element to apply a voltage to the conductive element. The method also includes coupling an additional electrode to the additional conductive element to provide an amplitude to determine a change in capacitance caused by a form alteration of at least one of the conductive element, the additional conductive element, and a space between the conductive element and the additional conductive element.

The amplitude may be determined by a capacitance between the conductive element and the additional conductive element. The additional conductive element may be substantially parallel to the conductive element.

Other features of the present embodiments will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 is a diagram of a capacitive strain gauge, according to one embodiment.

FIG. 2 is a cross-sectional view of a capacitive strain gauge, according to one embodiment.

FIG. 3 is an illustration of two flat caps and a bending beam, according to one embodiment.

FIG. 4 is a schematic diagram of two flat caps and interface circuitry, according to one embodiment.

FIG. 5 is a diagram of a capacitive strain gauge, according to one embodiment.

FIG. 6 is an electrical diagram of a capacitive strain gauge and a unity gain non-inverting amplifier, according to one embodiment.

FIG. 7 is an electrical diagram of a capacitive strain gauge and a unity gain non-inverting amplifier with resistors, according to one embodiment.

FIG. 8 is an electrical diagram of a capacitive strain gauge, according to one embodiment.

Other features of the present embodiments will be apparent from the accompanying drawings and from the detailed description that follows.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the claims. Furthermore, in the detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

A method and system of a capacitive strain gauge is disclosed. The capacitive strain gauge may be built using the principles of capacitance rather than resistance to overcome the limitations of the resistive strain gauge. A change below a threshold limit in the dimensions of the “flat capacitor” (hereafter flat cap) of the capacitive strain gauge disclosed herein may create substantial changes in capacitance above another threshold (e.g., leading to better measurement accuracy and resolution).

As a result, the flat cap may require limited initial compensation, have a reduced response to temperature, and include improved performance with respect to out-of-plain forces. In addition, a flat cap may use less physical height to construct a load measurement device than a conventional load cell.

A method employed to measure capacitance in the capacitive strain gauge may be a modulated carrier method. This may require a sensor capacitor of the capacitive strain gauge to have floating plates so that a voltage square wave of known frequency can be applied to one plate while the amplitude at the other plate is measured to determine capacitance. Furthermore, to overcome a problem of stray capacitance, a faraday guard shield 104 may be used around the capacitive strain gauge.

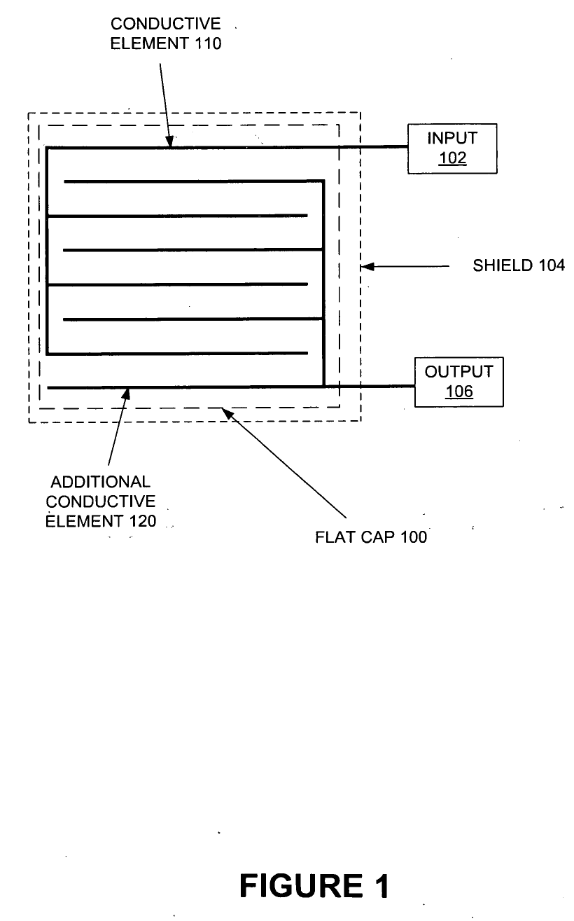

FIG. 1 is a diagram of a capacitive strain gauge, according to one embodiment, and includes an example of the flat capacitor of the capacitive strain gauge. FIG. 1 includes a flat cap 100, an input 102, a shield 104, an output 106, a conductive element 110, and an additional conductive element 120.

The shield 104, shown symbolically in FIG. 1, may be on top of and/or under the flat cap 100, which may be located in the middle and separated from the shields 104 by layers of printed circuit material. The shields may substantially surround (e.g., enclose) the flat cap 100. The trace widths of the capacitor and/or the space between traces may be 0.004 inches. The lengths of the capacitor “fingers” (e.g., a plurality of elongated members of a conductive element 110) may be 0.5 inches, and the overall width of the capacitor “comb” (e.g., a conductive element 110, an additional conductive element 120) may be 0.25 inches. In an embodiment, the conductive element may include only one “finger.” The conductive element may be substantially parallel to an additional conductive element.

The combined thickness of the FR4 and/or Kapton material, the flat cap 100 and faraday guard shields 104 may be 0.02 inches. The measured capacitance of the sensor capacitor may be approximately 11 PF in the embodiment illustrated in FIG. 1. In another embodiment, the capacitive strain gauge may be constructed using techniques similar to those used to manufacture a printed circuit board. For example, the fingers (e.g., the elongated member) of the capacitive comb (e.g., the conductive element 110) of the flat cap 100 may be copper traces, similar to traces on the printed circuit board.

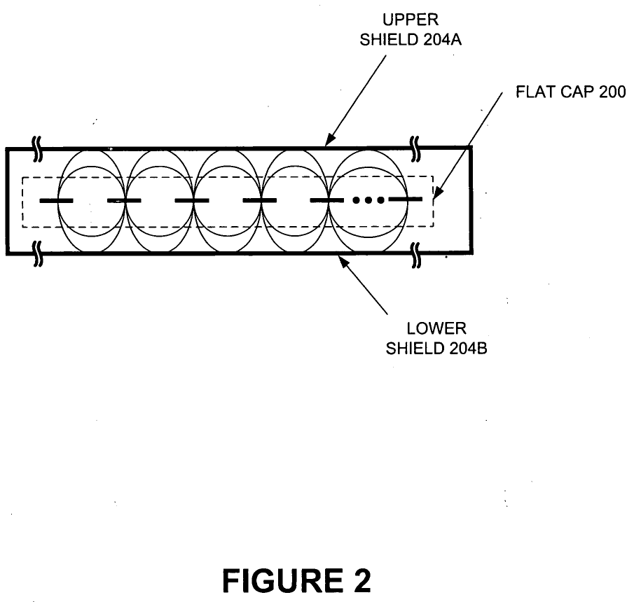

FIG. 2 is a cross-sectional view of a capacitive strain gauge, according to one embodiment. FIG. 2 illustrates a flat cap 200, an upper shield 204A, and a lower shield 204B. The dark dashed line in the center of FIG. 2 may represent the interspaced input 102 and output 106 plates of the flat cap 100 capacitor (see also FIG. 1). The curved lines in FIG. 2 may represent capacitive flux lines.

As shown in FIG. 2, some signal loss to the shields, which may be connected together, may occur. This may not affect the input fingers if the source of the input signal is from a low impedance device. However, a voltage divider may be formed between the shield and the capacitive output fingers to make a half bridge structure. The distance between plates of flat cap 200 and the shields (e.g., the upper shield 204A and/or the lower shield 204B) can be calculated to make this divider as close to two as possible. This flat cap 200/shield 204 divider can also be addressed in a number of other ways as described in this disclosure.

The capacitor plates and the shield may be separated by a material such as FR4 PCB material and/or Flex circuit kapton material. This material may be the dielectric medium for all capacitors formed within the structure. The fact that the dielectric is common to all capacitors may make any change in the dielectric material affect all capacitors proportionally. This may apply to dimensional changes (e.g., surface deformation, length alteration, shape alteration, proportional area alteration, etc.) due to temperature and/or dielectric constant changes due to moisture. The result is a stable capacitive strain gauge which may be primarily affected by dimensional changes due to changes in strain (e.g., a directional change of the surface) of the material to which the device is bonded.

A flat cap 200 may detect strain in a bending structure when it is bonded to the bending structure with the expected stress parallel to the “teeth” of the capacitor's input and output plates. The length of the “teeth” may increase and/or decrease (e.g., length alteration, shape alteration) as the bending structure's length increases and/or decreases in response to an applied force. The flat cap 200 may be used in any place that a resistive strain gauge may be used.

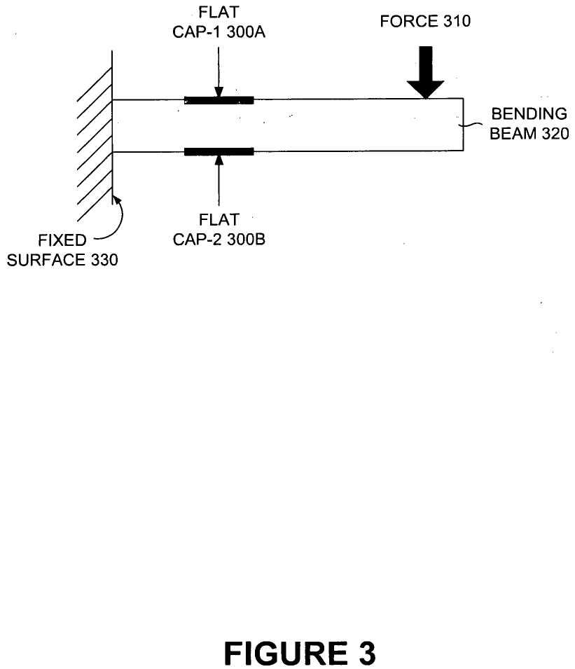

FIG. 3 is an illustration of two flat caps and a bending beam, according to one embodiment, and includes flat cap-1 300A, flat cap-2 300B, force 310, bending beam 320, and fixed surface 330. Strain (e.g., a directional change) may be measured on the bending beam 320 when a force 310 is applied. The bending beam 320 is held in place by the fixed surface 330. When the beam 320 is deflected downwards by the force 310, the top surface may experience an expansion, while the bottom surface may experience a contraction. The equivalent of a full bridge circuit may be formed when one flat cap 200 is bonded to one side of a bending beam and another is bonded to the opposite side. In this configuration, while one capacitor is increasing in capacitance, the other may be decreasing.

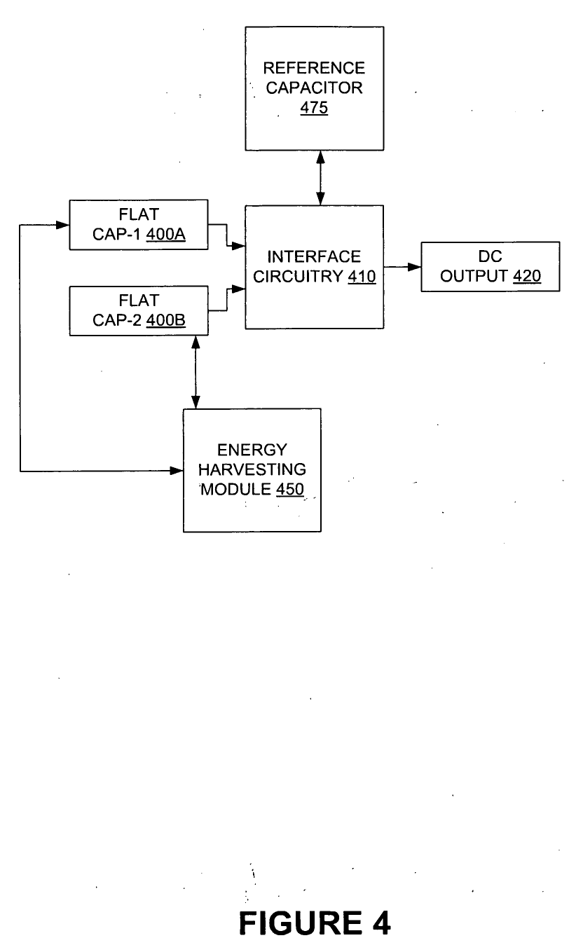

FIG. 4 is a schematic diagram of two flat caps and interface circuitry, according to one embodiment. FIG. 4 includes flat cap-1 400A, flat cap-2 400B, interface circuitry 410, DC output 420, an energy harvesting module 450, and a reference capacitor 475.

The output from two flat capacitors (e.g., flat cap-1 400A, flat cap-1 400B) may be input to a differential amplifier where the difference in the two signals can be detected, amplified and then converted by the interface circuitry 410 to a DC voltage 420. In an embodiment, the DC voltage 420 may be calibrated to represent the amount of force or weight applied to the open end of the beam. The amplitude of the output voltage may depend on the gain of the differential amplifier. In this setup, the gain may be ten, and the DC voltage 420 may be approximately 0.001 volts per pound of applied weight.

Some advantages of the capacitive strain gauge built using this method may include the following aspects.

Large signal to noise ratio. A capacitive strain gauge may provide a signal change that is 10 to 100 times larger than a resistive type of strain gauge.

Temperature resistance. The resistive material in a resistive strain gauge may be affected by temperature. A capacitive strain gauge may be affected by temperature to a substantially lower degree. The current carrying material in a capacitive strain gauge may be a low impedance conductor such as copper. While a dimensional change caused by temperature in a resistive strain gauge may cause a change in resistance that appears identical to strain, a dimensional change in a capacitive strain gauge caused by temperature may not result in a significant change in output. Given that a dimensional change of a capacitive strain gauge based on temperature may be proportional in all directions, the temperature change may not result in a significant change in capacitance in a flat cap.

Off-axis sensitivity. In a bending beam test structure, torque may produce an off-axis change in dimension in the surfaces to which the flat caps (e.g., flat cap-1 300A, flat cap-2 300B) are attached. While a resistive strain gauge may produce altered results based on off-axis strain, the capacitive strain gauge (e.g., flat cap 100) may experience a substantially lower altered signal. A resistive strain gauge, on the other hand, may result in a substantial change in resistance and sensor output with strain components in off-axis directions.

Gauge factor. The gauge factor of a resistive strain gauge may be approximately 2 with an approximately 1% delta factor. Manufacturers may measure and print the actual gauge factor on packaging of a resistive strain gauge. The gauge factor of the capacitive strain gauge disclosed herein may always be 1, and a tolerance may be less than 1%.

Manufacturability. The flat cap may be manufactured with lot to lot dependencies below a threshold number. The threshold number may be negligible. The lot to lot dependencies for capacitive strain gauges may be lower than for a type of resistive strain gauge.

In an additional embodiment, the capacitive strain gauge system may include an energy harvesting module 450 that acquires energy from the environment to power the capacitive strain gauge when it measures a change in capacitance. The energy acquired may be from temperature changes, radiation, kinetic energy. Some forms of energy harvesting may include piezoelectric crystals or fibers that generate a voltage whenever they are mechanically deformed. Other methods for acquiring power include the pyroelectric effect, which converts a temperature change into electrical current or voltage, and thermoelectric effects, in which a thermal gradient formed between two dissimilar conductors produces a voltage. The energy acquired by the energy harvesting module 450 may be stored in a battery, a capacitor, or as potential energy in a mechanical device, such as a spring.

In an additional embodiment, a reference capacitor 475 may generate a capacitance based on one or more environmental factors (e.g., a humidity, a temperature, an air pressure, a radiation, etc.). The reference capacitor may be constructed in a form similar to the flat cap (e.g., the flat cap-1 400A), but a form change of the surface may result in a negligible change in capacitance of the reference capacitor 475.

The reference capacitor 475 may be coupled to the flat cap (e.g., the flat cap 100) system and/or the interface circuitry 410. In an embodiment, the reference capacitor 475 may be located in the shield of the flat cap (e.g., the flat cap-1 400A, the flat cap-2 400B). The reference capacitor 475 may enable an environmental factor to be removed from the measurement of capacitance generated by the flat cap when the surface is changed in form.

In another embodiment, multiple flat caps may be used together on the same surface to detect an uneven force applied to the surface. In the beam example of FIG. 3, the force 310 may be distributed unevenly across an area of the end of the bending beam 320. An uneven distribution of force 310 over an area of the end of the beam may result in an uneven deflection of the beam. The uneven deflection of the beam may correspond to varying degrees of strain in terms of compression and/or expansion of a surface, which may be detected using multiple flat caps (e.g., flat cap-1 400A, flat cap-2 400B). In this embodiment, flat cap-1 400A and flat cap-2 400B may be coupled to the same side of the beam to monitor a distribution of strain across the bending beam. The interface circuitry 410 may generate a DC output 420 to represent the total force applied to an object.

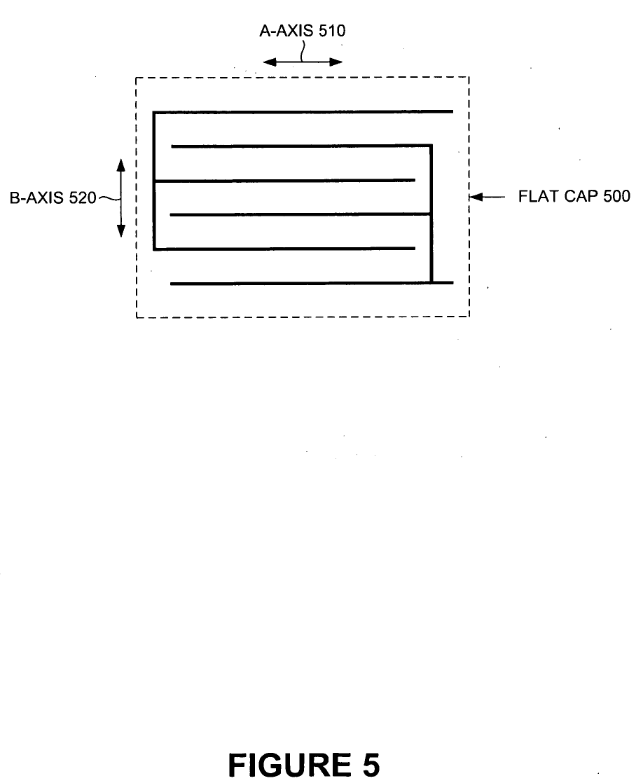

FIG. 5 is a diagram of a capacitive strain gauge, according to one embodiment. FIG. 5 includes flat cap 500, A-axis 510, and B-axis 520. FIG. 5 illustrates axis on which compression and/or expansion may affect capacitance in the flat cap 500.

Stress along the A-axis 510 may result in a change in capacitance because the “teeth” (e.g., an elongated member of the conductive element, an additional elongated member of the additional conductive element) of the capacitive comb are stretched. Stress along the A-axis 510 may leave the gap (e.g., the spaces between the teeth, the space between the conductive element and the additional conductive element) substantially unchanged. Stress along the B-axis 520 may result in a substantially lower change in capacitance because both the width area of the traces (e.g., the elongated member) and the “gaps” may be changed proportionately.

In another embodiment, the components of the flat cap 500 may be attached to a surface such that strain along the B-axis 520 results in a change in the space between the conductive elements of the flat cap 500 and a disproportionate change in the width area of the traces. In an embodiment, when strain occurs along the B-axis 520, the width area of the space between the traces may be changed while the areas of the traces (e.g., the elongated member of the conductive element) are preserved.

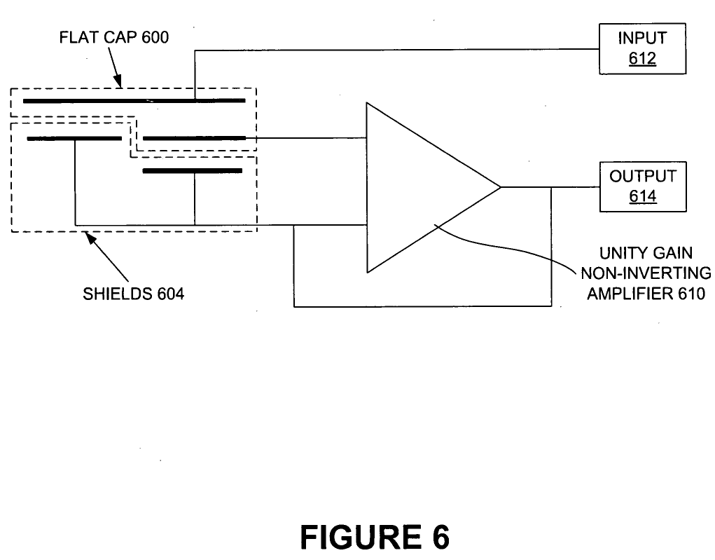

FIG. 6 is an electrical diagram of a capacitive strain gauge and a unity gain non-inverting amplifier, according to one embodiment. FIG. 6 includes flat cap 600, shields 604, unity gain non-inverting amplifier 610, input 612, and output 614.

FIG. 6 shows a simplified diagram of the electronics of the flat cap 600, according to one embodiment. The variable flat cap 600 and the shields 604 are represented as lines. In this example the amplifier is connected as a unity gain non-inverting amplifier 610 and provides a low impedance source (e.g., output 614) to the outside world and a bootstrap potential for substantially reducing the capacitance of the shields 604. The amplifier may have an offset temperature drift lower than a threshold limit. Input 612 may provide a mechanism to provide the flat cap 600 with a square wave voltage to provide a means to determine changes in capacitance at output 614.

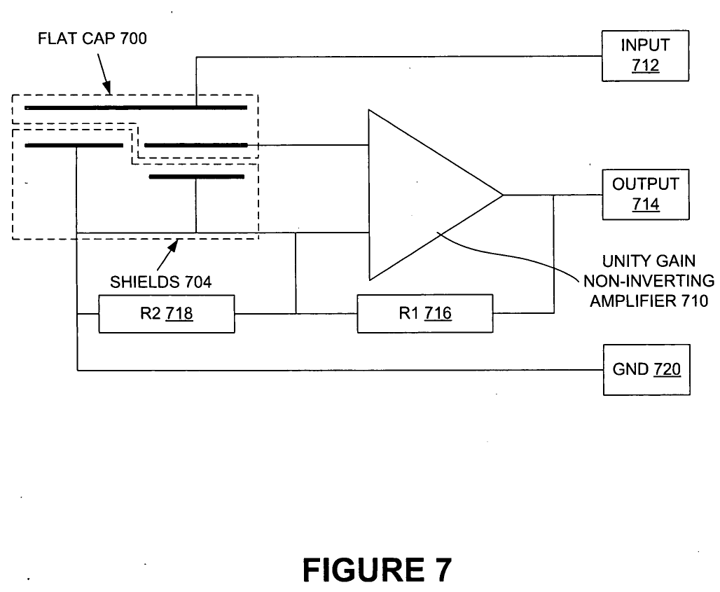

FIG. 7 is an electrical diagram of a capacitive strain gauge and a unity gain non-inverting amplifier with resistors, according to one embodiment. FIG. 7 includes flat cap 700, shields 704, unity gain non-inverting amplifier 710, input 712, output 714, R1 716, R2 718, and GND 720.

In FIG. 7, the shields 704 are grounded and resistors R1 716 and R2 718 may give the non-inverting amplifier enough gain to compensate for the loss of the voltage divider formed by the flat cap output plates and the shield. The amplifier may still provide a low impedance source to the outside world. A low temperature offset drift amplifier may be used as well as resistors (e.g., R1 716, R2 718) with very low temperature coefficients.

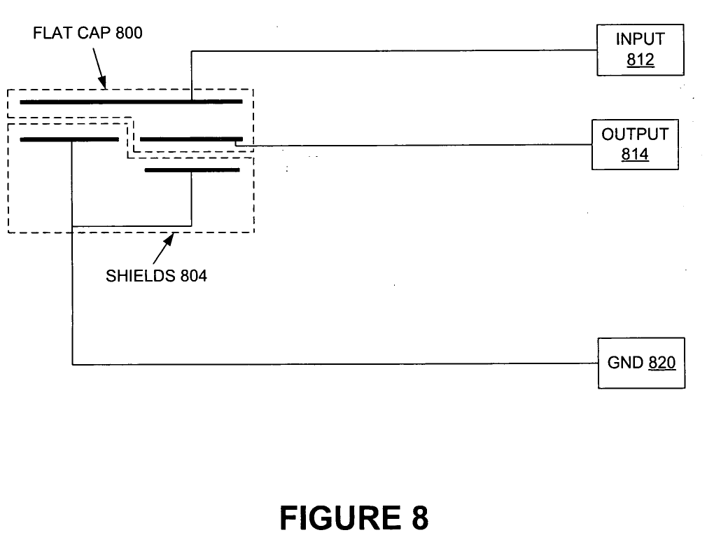

FIG. 8 is an electrical diagram of a capacitive strain gauge, according to one embodiment. FIG. 8 includes flat cap 800, shields 804, input 812, output 814, and GND 820. FIG. 8 shows connections when no amplifier is used.

The capacitive strain gauge may be operated without an amplifier for more hostile environments (e.g., higher and/or lower temperatures, reduced power availability, high vibration and/or shock prone, space availability, etc.) where the amplifier may experience problems (e.g., improper functioning, signal noise, failure of a component). The embodiment may require only three connections.

In one embodiment, the capacitive strain gauge may be built using parallel capacitive plates rather than springs, which may be used in a resistive strain gauge. The capacitive strain gauge illustrated in FIGS. 1-8 may be constructed to be more sensitive to strain in one axis (e.g., vertical) than another axis (e.g., horizontal). Markings outside the active area of the capacitive strain gauge of FIGS. 1-8 may help to align the capacitive strain gauge during installation.

In an embodiment, the capacitive strain gauge (e.g., flat cap 100, 200, 300A, 300B, 400A, 400B, 510, 520, 600) may be used to measure deformation (strain) of an object. The capacitive strain gauge may consist of an insulating flexible backing which supports a series of flat, capacitive plates (e.g., conductive elements) forming a series of capacitors. The capacitive strain gauge may be attached to an object by a suitable adhesive, such as cyanoacrylate. As the object is deformed (e.g., lengthened, compressed, changed in form, etc.) the distance between plates of the capacitors of the capacitive strain gauge may be changed, which may cause a change in capacitance of the strain gauge. Alternatively, the size of the plates may changes, causing a change in an area under the plates, which may cause a change in capacitance of the strain gauge.

The capacitive strain gauge may be ideal to measure the growth of a crack in a masonry foundation (e.g., of a bridge). In addition, the capacitive strain gauge may be preferred over the traditional resistive strain gauge to measure movement of buildings, foundations, and other structures because of the advantages discussed herein. In addition, the capacitive strain gauge may be built to work through a USB interface, the Internet, and/or a wireless network using Bluetooth, WiFi, and/or Zigbee.

Although the present embodiments have been described with reference to specific example embodiments, it will be evident that various modifications and changes may be made to these embodiments without departing from the broader spirit and scope of the various embodiments. For example, a combination of software and hardware may be used to enable the capacitive strain gauge disclosed herein to further optimize function.

It will be appreciated that the various operations, processes, and methods disclosed herein may be embodied in a machine-readable medium and/or a machine accessible medium compatible with a data processing system (e.g., a computer system), and may be performed in any order. The structures and/or modules in the figures are shown as distinct and communicating with only a few specific structures and not others. The structures may be merged with each other, may perform overlapping functions, and may communicate with other structures not shown to be connected in the Figures. Accordingly, the specification and drawings are to be regarded in an illustrative rather than a restrictive sense.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A system, comprising:
a conductive element of a capacitive structure attached to a surface, wherein the conductive element is comprised of an elongated member;
an additional conductive element of the capacitive structure attached to the surface, wherein the additional conductive element is comprised of an additional elongated member;
an electrode coupled to the conductive element that applies a voltage to the conductive element when a capacitance is being determined; and
an additional electrode coupled to the additional conductive element that receives an amplitude to determine a change in capacitance caused by a shape alteration of at least one of the conductive element, the additional conductive element, and a space between the conductive element and the additional conductive element.

2. The system of claim 1, wherein the additional conductive element is substantially parallel to the conductive element.

3. The system of claim 1, wherein the conductive element is comprised of a plurality of elongated members coupled together, and wherein the additional conductive element is comprised of a plurality of additional elongated members coupled together.

4. The system of claim 1, further comprising a shield that substantially covers the conductive element and the additional conductive element to reduce a stray capacitance.

5. The system of claim 4, wherein the shield substantially surrounds the conductive element and the additional conductive element.

6. The system of claim 5 further comprising an amplifier module to reduce a capacitance of the shield below a threshold level.

7. The system of claim 1, wherein a form change of the surface determines the shape alteration of at least one of the conductive element, the additional conductive element, and a shape between the conductive element and the additional conductive element.

8. The system of claim 7, wherein a capacitance change results from the shape alteration of at least one of at least one of the conductive element, the additional conductive element, and a space between the conductive element and the additional conductive element.

9. The system of claim 7, wherein a form change of the surface causes a proportional area alteration of a conductive element and a shape and causes a capacitance change below a threshold level.

10. The system of claim 1 further comprising a common dielectric used between each capacitive structure in the system to make an environmental condition affect each capacitive structure proportionately.

11. The system of claim 1, further comprising a reference capacitive structure coupled to the system to generate a capacitance based on an environmental factor and to compensate a measurement affected by the environmental factor.

12. The system of claim 1, further comprising a plurality of capacitive structures coupled to the surface, wherein a difference in capacitance between the plurality of capacitive structures is used to detect an uneven force when it is applied to the surface.

13. The system of claim 1, further comprising an energy harvesting module that acquires power to apply the voltage to the conductive element.

14. A method, comprising:
altering a shape of a part of a capacitive structure using a form change of a surface, wherein the capacitive structure is comprised of a conductive element, an additional conductive element, and a space between the conductive element and the additional conductive element;
applying a voltage to an electrode coupled to the conductive element; and
detecting an amplitude of an additional electrode coupled to the conductive element to determine a change in capacitance of the capacitive structure caused by a shape change of the surface.

15. The method of claim 14, wherein the additional conductive element is substantially parallel to the conductive element.

16. The method of claim 14, wherein the conductive element is comprised of a plurality of elongated members coupled together, and wherein the additional conductive element is comprised of a plurality of additional elongated members coupled together.

17. The method of claim 14, further comprising reducing a stray capacitance using a shield that substantially covers the conductive element and the additional conductive element.

18. A method, comprising:
forming a conductive element of a capacitive structure attached to a surface, wherein the conductive element is comprised of an elongated member;
placing an additional conductive element in the capacitive structure attached to the surface, wherein the additional conductive element is comprised of an additional elongated member;
coupling an electrode to the conductive element to apply a voltage to the conductive element; and
coupling an additional electrode to the additional conductive element to provide an amplitude to determine a change in capacitance caused by a form alteration of at least one of the conductive element, the additional conductive element, and a space between the conductive element and the additional conductive element.

19. The method of claim 18, wherein the amplitude is determined by a capacitance between the conductive element and the additional conductive element.

20. The method of claim 18, wherein the additional conductive element is substantially parallel to the conductive element.
